(19) United States
(12) Patent Application Publication
(10) Pub. No.: US 2010/0174970 A1
(43) Pub. Date: Jul. 8, 2010

(54) EFFICIENT IMPLEMENTATION OF A KEY-EQUATION SOLVER FOR BCH CODES

(75) Inventor: Koby Goldberg, Holon (IL)

Correspondence Address: KEVIN D. MCCARTHY;ROACH BROWN MCCARTHY & GRUBER, P.C., 424 MAIN STREET, 1920 LIBERTY BUILDING, BUFFALO, NY, 14202, US

(73) Assignee: HORIZON SEMICONDUCTORS LTD., Herzliya (IL)

(21) Appl. No.: 12/348,471

(22) Filed: Jan. 5, 2009

(51) Int. Cl. H03M 13/07; G06F 11/10

(52) U.S. Cl. 714/785; 714/E11.032

(57) ABSTRACT

The present invention relates to a method for solving the key equation and finding the error locator polynomial coefficients of a received word comprising the steps of: (a) providing the syndrome elements of said received word; (b) initializing said coefficients of said error locator polynomial; (c) providing an auxiliary polynomial; (d) initializing said auxiliary polynomial coefficients; (e) processing said syndrome elements and said auxiliary polynomial coefficients for iteratively updating said coefficients of said error locator polynomial; and (f) outputting said updated coefficients of said error locator polynomial.

### FIELD OF THE INVENTION

The present invention relates to the field of BCH error correcting codes. More particularly, the invention relates to a method and apparatus for efficiently solving the key-equation which is an integral part of the BCH decoder process widely used for correcting multiple random error patterns in variable-length digital codes.

### BACKGROUND OF THE INVENTION

During the transmission of data, through a variety of communication channels, noise, caused by the transmission path, can introduce errors in the transmitted data. Thus typically, the received error-infested data is diverse from the initial transmitted data. Therefore, in order to cope with these errors, various methods and techniques have been developed to detect and correct errors of transmitted data. One of the popular methods, for correcting transmission errors, includes generating a codeword which includes a message part (the data intended for transmission) and a parity part (redundancy information used for performing error correction), which can be used after transmission for reconstructing the initial message.

Some of the well-known error-correcting codes are the BCH (Bose-Chaudhuri-Hocquenghen) codes which are among the most widely used for communication and storage systems. The mathematical basis of BCH codes and a thorough description of the BCH decoding process can be found in:

“Error Control Coding” by Shu Lin and Daniel J. Costello, Jr., Pearson Prentice Hall, New Jersey, 2004; “Algebraic Coding Theory”, E. R. Berlekamp, McGraw-Hill, New York, 1968; and “Theory and Practice of Error Control Codes”, Richard E. Blahut, Addison-Wesley, 1983.

A binary (N, K) BCH code has K message symbols and N coded symbols, where each symbol is ‘0’ or ‘1’ and all the mathematical operations are performed under Galois Field of GF(2^{m}). A binary (N, K) BCH code can correct up to t errors. For binary BCH codes, an error can be corrected simply by finding out the error location and inverting the binary value at that location.

The method steps of a typical BCH decoder used for the correction of errors can be summarized in three steps: (1) calculating the syndrome elements from the received codeword, (2) solving the key equation, also known as determining the Error Location Polynomial (ELP) from the syndrome elements (3) finding the error locations in the received word using the ELP, also known as Chien Search and correcting those errors. The second step, i.e. solving the key equation, is considered, mathematically, the hardest part of the decoding process.

FIG. 1 is a block diagram of a typical binary BCH decoder architecture. The received data, R(x), is first fed into the syndrome calculator 100 for generating the syndrome elements Sⱼ representing the error pattern of the received word from which the errors can be corrected. The syndrome Sⱼ is then fed to the key equation solver 200 for generating an error locator polynomial V(x). The error locator polynomial roots indicate the location(s) of the error(s). Next, the error locator polynomial V(x) is passed to a Chien search engine & error corrector 300 for correcting the errors on the received data R(x). The Chien search generates the root(s) representing the location(s) of the errors and the error corrector inverts the binary values of these locations in the received data R(x), ideally producing the original transmitted codeword C(x). As stated above, the key equation solver 200 is considered, mathematically, the most complex part of the BCH decoder.

One of the techniques frequently used to solve the key equation is the Berlekamp-Massey algorithm. The disclosure of this algorithm for correcting the errors can be found in the “Lin & Costello” book or the “Blahut” article cited above.

Prior art technologies applied the traditional Euclidean algorithm (or variation thereof for the calculation of the ELP and designed circuits based upon these algorithms. However, these algorithms require a large number of registers, Finite-Field Multipliers (FFM) and perhaps Finite-Field Inverters (FFI). Each of the FFMs and FFIs hardware circuitry implementations occupies precious space on the integrated circuit chip. The known FFM hardware implementations are “board space” consuming and the FFI hardware implementations are even more “board space” consuming, or alternatively take a lot of clock cycles to evaluate. Therefore, it would be desirable to have an “inversionless” method and apparatus which requires no FFIs and minimizes the number of FFMs required for the implementation of the key equation solver. Although circuit space may be skillfully traded for process time, by implementing less hardware components and using the same components many times, however, in most cases process time is also precious and critical. Therefore, it is desirable to find a method for solving the key equation in an efficient manner by minimizing the total amount of multiplication operations needed.

In a paper titled “High-Speed Architectures for Reed-Solomon Decoders” by Dilip V. Sarwate & Naresh R. Shanbhag, IEEE Transactions on Very Large Scale Integration (VLSI) Systems, VOL. 9, No. 5, October 2001, an architecture for decoding codes with the Berlekamp-Massey algorithm is presented. The paper further discloses methods for improving the critical path in the known implementations and opening bottle necks. Nevertheless, the described method deals with the Reed-Solomon codes, which are non binary, and requires a total of 2t iterations.

US 2003/0131308 discloses a method and apparatus for solving the key equation of a decoded codeword. The disclosed method is based on the Euclidian algorithm for solving the key equation. The disclosed method is also capable of solving the key equation in a number of t iterations. However, the described method requires a large number of Finite Field multiplications for solving the key equation, which require large number of FFMs or alternatively small number of FFMs but many cycles of operation for reusing those FFMs many times

It is an object of the present invention to provide a method for efficiently decoding and correcting binary BCH codes.

It is still another object of the present invention to provide an efficient hardware implementation of a circuit capable of solving the key equation using a minimal number of hardware components and a minimal number of process iterations.

It is another object of the present invention to provide an apparatus for solving the key equation which requires no FFIs.

Other objects and advantages of the invention will become apparent as the description proceeds.

### SUMMARY OF THE INVENTION

The present invention relates to a method for solving the key equation and finding the error locator polynomial coefficients of a received word comprising the steps of: (a) providing the syndrome elements of said received word; (b) initializing said coefficients of said error locator polynomial; (c) providing an auxiliary polynomial; (d) initializing said auxiliary polynomial coefficients; (e) processing said syndrome elements and said auxiliary polynomial coefficients for iteratively updating said coefficients of said error locator polynomial; and (f) outputting said updated coefficients of said error locator polynomial.

Preferably, the processing of the syndrome elements and the auxiliary polynomial coefficients for iteratively updating said coefficients of said error locator polynomial is done for t iterations.

The present invention also relates to a system for solving the key equation and finding the error locator polynomial coefficients of a received word comprising: (a) a Discrepancy Processor capable of processing the syndrome elements of said received word with coefficients of said error locator polynomial for outputting an auxiliary scalar; (b) a Control unit for receiving said auxiliary scalar, processing said auxiliary scalar, and outputting: said auxiliary scalar, a second scalar, and a conditional control bit; and (c) an Error Locator Updater for receiving and processing: said auxiliary scalar, said second scalar, and said conditional control bit, in order to update said coefficients of said error locator polynomial.

### BRIEF DESCRIPTION OF THE DRAWINGS

In the drawings:

FIG. 1 is a block diagram of a typical binary BCH decoder architecture.

FIG. 2 is a block diagram depicting the key equation solver, according to one of the embodiments of the invention.

FIG. 3 is a block diagram depicting the Discrepancy Processor, according to one of the embodiments of the invention.

FIG. 4 is a block diagram of the Control unit between the Discrepancy Processor and the Error Locator Updater, according to one of the embodiments of the invention.

FIG. 5 is a block diagram of the Error Locator Updater, according to one of the embodiments of the invention.

### DETAILED DESCRIPTION OF PREFERRED EMBODIMENTS

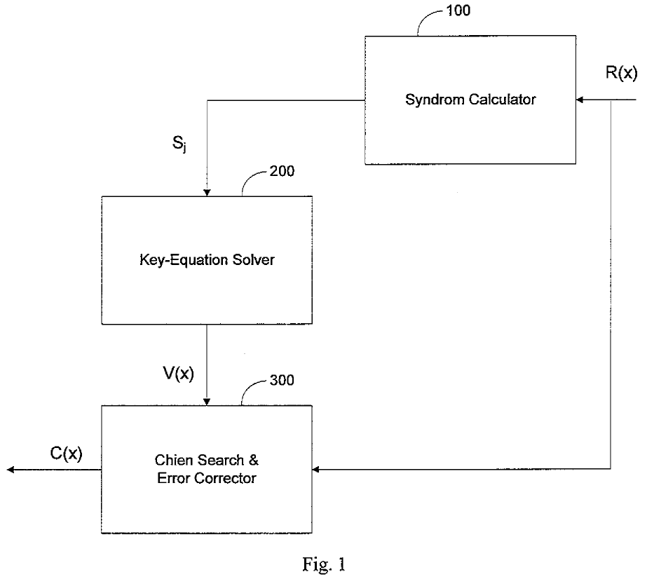

As discussed in the background, in relations to FIG. 1, the most complicated part of the BCH decoder method is the solving of the key equation, i.e. finding the ELP (Error Locator Polynomial) coefficients. In this part, the syndrome polynomial elements (Sⱼ) are processed for finding the ELP coefficients (Vᵢ) which are used for locating and correcting the errors in the received word. The basic approach to obtain the Vᵢ from the Sⱼ is by solving the following equations, known also as Newton's identities:

$${S}_{1} - {V}_{1} = 0$$

$${S}_{2} - {V}_{1} {S}_{1} + 2 {V}_{2} = 0$$

$$…$$

$$…$$

$$…$$

$${S}_{k} - {V}_{1} {S}_{k - 1} + … + {( - 1 )}^{k - 1} {V}_{k - 1} {S}_{1} + {( - 1 )}^{k} k {V}_{k} = 0$$

For binary codes the Sⱼ and Vᵢ are both from the Galois Field GF(2^{m}) and the even equations are dependent on the odd equations (a full disclosure of why this is true can be found in the “Lin & Costello” book chapter 6). Therefore, the problem may be reduced only to the odd equations:

$${S}_{1} + {V}_{1} = 0$$

$${S}_{3} + {S}_{1}^{2} {V}_{1} + {S}_{1} {V}_{2} + {V}_{3} = 0$$

$$…$$

$$…$$

$$…$$

Nevertheless, direct solution for this set of equations would require a very complex hardware implementation (for example the Gauss Elimination algorithm for solving linear equations, requires polynomial complexity).

The method of the invention, according to one of the embodiments, for solving the key equation and finding the ELP coefficients, is best understood by the following decoding process:

At first the syndrome elements should be calculated from the received R(x) data transmission and are referred to as follows:

Sⱼ=R(α^{j}), j=1, 2, . . . , 2t

where t is the number of errors the BCH code is designed to correct.

Initial Conditions:

k(0)=0

γ(0)=1

V₀(0)=1, V₁(0)=V₂(0)= . . . =Vₜ(0)=0

b₀(0)=1, b₁(0)=b₂(0)= . . . =bₜ(0)=0

where both k(0) and γ(0) are scalar variables, and bᵢ(0) are the initial coefficients of an auxiliary polynomial h(x). Vᵢ(o) are the initialized coefficients of the ELP: V(x).

The Set Values for all Iterations:

V₋₁(r)=0

b₋₁(r)=0, b₋₂(r)=0

where r is an integer used as an iteration index.

After the t^{th} iteration (r=t) Vᵢ(r) are the desired coefficients of the ELP and bᵢ(r) are the coefficients of the auxiliary polynomial used in the process, where i=0 1, 2, . . . , t.

The Process of the Method according to an Embodiment:

For the first iteration the following steps should be carried out starting with r=0. For each new iteration, r increases by 1 and the following steps are carried out again with the new r. The process continues t times, until r=(t−1), including.

Step 1: Calculating the Discrepancy δ(r):

$$\begin{matrix}δ ( r ) = {\sum }_{j = 0}^{min ( 2 r , t )} {S}_{2 r + 1 - j} \cdot {V}_{j} ( r ) \\ = {S}_{2 r + 1} {V}_{0} ( r ) + {S}_{2 r} {V}_{1} ( r ) + \\ {S}_{2 r - 1} {V}_{2} ( r ) + … + {S}_{2 r + 1 - t} {V}_{l} ( r )\end{matrix}$$

Step 2: Iteratively Updating the ELP Coefficients:

Vⱼ(r+1)=γ(r)·Vⱼ(r)+δ(r)·bⱼ₋₁(r), j=0, 1, 2, . . . , t

Step 3: Iteratively Updating bⱼ(r), γ(r) and k(r):

If δ(r)≠0 and k(r)≧0, then proceed as follows:

bⱼ(r+1)=Vⱼ₋₁(r), j=0, 1, 2, . . . , t

γ(r+1)=δ(r)

k(r+1)=−k(r)

Else, proceed as follows:

bⱼ(r+1)=bⱼ₋₂(r), j=0, 1, 2, . . . , t

γ(r+1)=γ(r)

k(r+1)=k(r)+1

The Outcome:

The coefficients Vⱼ(t) are the coefficients of the desired ELP:

$$V ( x ) = {\sum }_{j = 0}^{l} {V}_{j} ( t ) \cdot {x}^{j} = {V}_{0} ( t ) + {V}_{1} ( t ) x + {V}_{2} ( t ) {x}^{2} + … + {V}_{i} ( t ) {x}^{i}$$

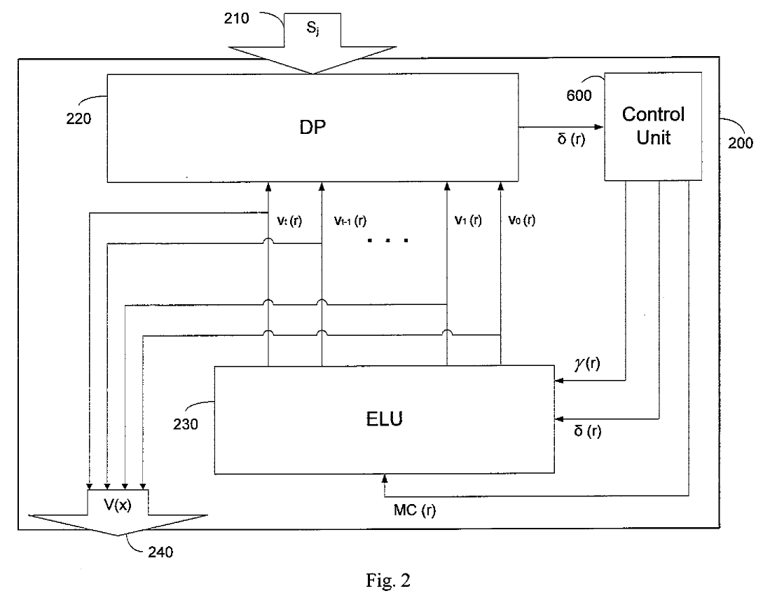

For the sake of enablement an example of a hardware implementation of the above method is set forth, although many embodiments and implementations are possible for realizing the method of the invention. FIG. 2 is a block diagram depicting the key equation solver 200, as described in relations to FIG. 1, according to one of the embodiments of the invention. At first Discrepancy Processor (DP) 220 receives the syndrome elements Sⱼ from bus 210 and the initial ELP coefficients Vᵢ(0) from Error Locator Updater (ELU) 230. The syndrome elements are then processed, in DP 220, together with the corresponding ELP coefficients Vᵢ(0), for formulating the δ(0) which is sent to the Control unit 600. Control unit 600 receives the δ(0) and outputs γ(0) and δ(0) variables and the conditional signal MC(0) to ELU 230. These three signals γ(0), δ(0) and MC(0) are used to calculate the next iteration of the ELP coefficients V₁(1) which will emit from the ELU 230 in the next iteration. The described process continues for t iterations, where each iteration DP 220 receives the new ELP coefficients Vᵢ(r) from ELU 230. These new ELP coefficients Vᵢ(r) are processed with the syndrome elements stored within for formulating the δ(r) which is sent to the Control unit 600. Each iteration the Control unit 600 receives the δ(r) and outputs γ(r) and δ(r) variables and the control signal MC(r) to ELU 230. In each iteration these three signals γ(r), δ(r) and MC(r), are used to manipulate the next iteration value of the ELP coefficients Vᵢ(r+1) which will be emitted from the ELU 230 on the next iteration. When the t iterations are finished, the Vᵢ(r) at that point, i.e. the ELP coefficients Vᵢ(t), are sent on bus 240 to the Chien Search & error corrector unit (not shown).

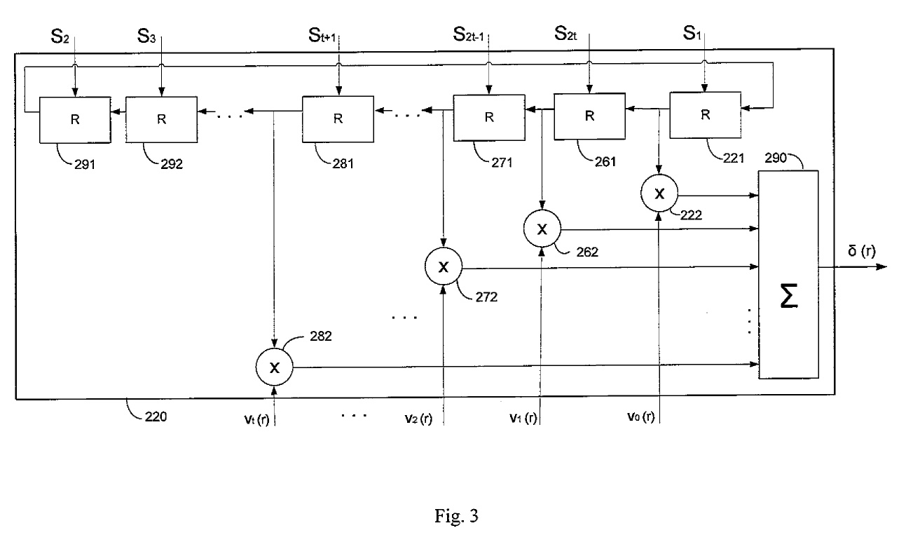

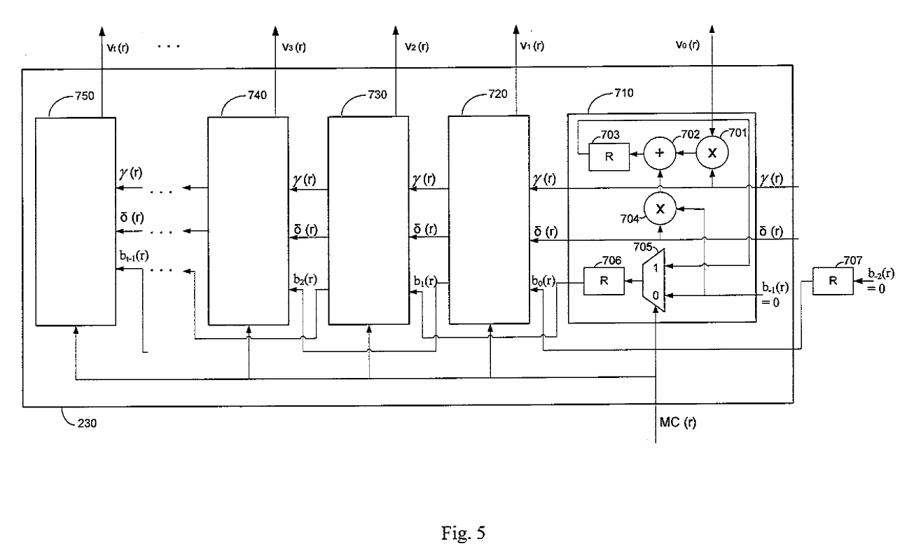

FIG. 3 is a block diagram depicting the DP 220 described in relations to FIG. 2, according to an embodiment of the invention. The DP 220 is an implementation of step 1 of the process described above according to one embodiment. The directions (e.g. of left and right) used hereinafter are only for the sake of brevity and should not be taken literally; the physical implementation and logical connections of the described circuits may be done in other ways. At first, all the syndrome elements are loaded into the registers of DP 220, where the term register refers hereinafter to include any memory module used for storing one or more bits. The first syndrome element S₁ is loaded into the right most register 221 whereas the rest of the elements are loaded in ascending order from left to right. Meaning that the second syndrome element S₂ is loaded to the left most register 291, the third syndrome element S₃ is loaded to register 292, and so on, including the (t+1)th syndrome element Sₜ₊₁ which is loaded into register 281 and the concluding of the last syndrome elements S₂ₜ₋₁ and S₂ₜ which are loaded into registers 271 and 261 respectively. The Vᵢ(r) polynomial coefficients are received from the ELU 230, which will be described later in relations to FIG. 5, and multiplied each with its corresponding syndrome element. All the corresponding multiplication results, e.g. from FFMs 222, 262, and 282, are added together in adder 290 for producing the discrepancy result, symbolized as δ(r). Thus for example, in the first iteration, where r=0, the first coefficient V₀(0) is multiplied with the first syndrome element S₁ by FFM 222 and the result is sent to Finite Field Adder (FFA) 290. As stated in relations to the initial conditions of the described method, the V₀(0)=1 and all the rest of the Vᵢ(0) coefficients are null, therefore, δ(r) of the first iteration will be S₁. Before the next iteration, all the set values stored in the registers are left shifted twice in a closed cycle. Meaning that the syndrome element S₁ value is shifted to the register 271, S₂ value is shifted to the register 261, S₃ value is shifted to the register 221, and so on. After the shifting, the new coefficients of the Vᵢ(r) are multiplied, each with its corresponding syndrome element. Thus in the second iteration, where r=1, the first coefficient V₀(1) is multiplied with the value of syndrome element S₃ by multiplier 222 and the result is sent to adder 290, the second coefficient V₁(1) is multiplied with the value of syndrome element S₂ by multiplier 262 and the result is sent to adder 290, the third coefficient V₂(1) is multiplied with the value of syndrome element S₁ by multiplier 272 and the result is sent to adder 290, and so on where the rest of Vᵢ(1) are null. All the results from all the multipliers are then added by adder 290 and the resulting δ(1) is outputted. Hence, before each iteration, all the values stored in the registers are left shifted twice in a closed cycle, after which each of the shifted values is multiplied with its corresponding new Vᵢ(r) polynomial coefficient. The results from the multipliers are then sent to adder 290 and the total sum δ(r) is then outputted. As shown in FIG. 3, there are 2t registers for storing the syndrome elements and there are only t+1 multipliers and t+1 coefficients Vᵢ(r), therefore only the t+1 right registers (e.g. 221, 261, and 281) values are multiplied with the Vᵢ(r) values.

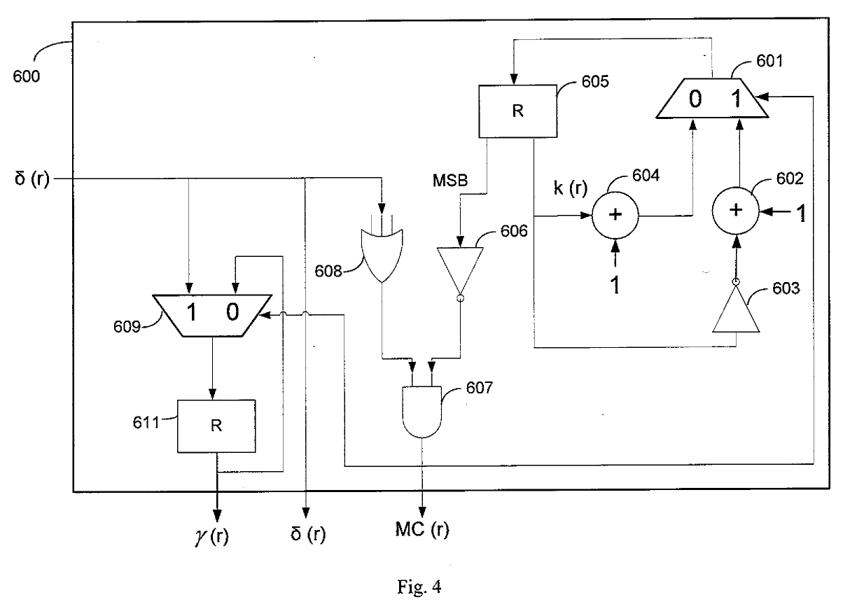

FIG. 4 is a block diagram of the Control unit 600 described in relations to FIG. 2. The control unit 600 is a partial implementation of step 3 of the process described above according to one embodiment. Control unit 600 first receives the discrepancy δ(r) and checks if δ(r)≠0 by checking all of δ(r) bits in OR gate 608. OR gate 608 may have a number of inputs according to the bit-size of δ(r) (since the calculations are performed under GF(2^{m}), δ(r) is m bits long). OR gate 608 will yield a ‘0’ if and only if δ(r) value is in fact a null, Simultaneously, the value of k(r) stored in register 605, is checked to see if k(r)≧0. A positive value has a null in its MSB (the sign bit in 2's complement representation), and therefore if the value stored in register 605 is positive its MSB will be 0. The inverted MSB from inverter 606 and the result of OR 608 are fed into AND gate 607 and the result is symbolized as MC(r), which in fact indicates the condition of step 3: “If δ(r)≠0 and k(r)≧0”. The conditional bit MC(r) is then used for determining γ(r+1), k(r+1), and bⱼ(r+1). The MC(r) is used to control MUX 609, which determines if the current γ(r) or δ(r) is loaded into register 611 as γ(r+1). The δ(r) is fed from the incoming input δ(r) and the γ(r) is fed from register 611. The new value from MUX 609 is then stored in register 611, and will be used in the next iteration for γ(r+1). Likewise the MC(r) is also used for determining the k(r+1). The MC(r) is used to control MUX 601 which determines whether the k(r)+1 (1 is added by full adder 604), is loaded into register 605 for storing as k(r+1), or −k(r) is loaded into register 605 for storing as k(r+1). According to the “2's complement” representation technique, in order to attain the value of −k(r) the value k(r) is first loaded from register 605 and each of its bits is inverted, by inverter 603, after which 1 is added to the result by binary adder 602. The value stored in register 605 will be used in the next iteration as the new k(r+1). Thus the three variables γ(r), δ(r) and MC(r) are attained for output; the δ(r) is outputted as received, the γ(r) is outputted from register 611, and the MC(r) is derived from AND gate 607. As derived from the initial conditions of process of the invention, register 605 is first loaded with a value of ‘0’ and register 611 is first loaded with a value of ‘1’, before the iterations begin. For example, if in the first iteration the received δ(0) is not a null, then AND gate 607 yields a ‘1’ for MC(0), since value stored in register 605 is ‘0’. The MC(0) which is a ‘1’, the received 6(0), and γ(0) stored in register 611, which is a ‘1’, are first outputted. MUX 609, upon receiving a ‘1’ delivers the incoming δ(0) into register 611. Simultaneously, MUX 601 upon receiving a ‘1’ delivers the “2's complement” inverse of ‘0’ (i.e. the value stored in register 605) which is a ‘0’ into register 605.

FIG. 5 is a block diagram of the ELU 230 described in relations to FIG. 2. The ELU 230 is an implementation of step 2 and a partial implementation of step 3 of the described above process of the invention according to one embodiment. When ELU 230 receives the inputs γ(r), δ(r) and MC(r), they are fed to block 710, which is a Processing Element (PE) of the FLU 230. Before starting the process, register 706 is initialized with a ‘0’ and registers 703 and 707 are initialized with a ‘1’ according to the initial conditions disclosed in relations to the described above process of the invention. At first, the value b₁(r) stored in 706 is sent to block 730 as input and the value V₀(r) stored in register 703 is transmitted as output from ELU 230. The same value V₀(r) stored in register 703 is also fed to MUX 705 together with the value of b₋₁(r) which is a null as stated above in the initial conditions of the process. The MUX 705 is controlled by the conditional bit MC(r) which decides if register 706 receives the V₀(r) value, from register 703, or the b_{'1}(r) value. Therefore, the new value of register 706 is now equal to the b₁(r+1) and will be used in the next iteration. From a different rout, the γ(r) input is multiplied, by FFM 701, with the V₀(r) value stored in register 703. Simultaneously, δ(r) input is multiplied, by FFM 704, with the value of b₋₁(r) (which is a null as stated in the initial conditions of the process). The results from both multipliers 701 and 704 are added by GF(2^{m}) FFA 702 (which is a bitwise XOR) and stored in register 703 as V₀(r+1) for the next iteration. The inputs γ(r) and δ(r) are also transmitted to block 720. Blocks 720, 730, 740, and 750 are also PEs and perform similarly to PE 710 with a similar internal hardware arrangement. As shown in FIG. 5, (t+1) PEs are implemented in order to produce the (t+1) ELP coefficients V₀(r) to Vₜ(r). Nevertheless, although PE 710 receives the b₋₁(r)=0 input, and although PE 720 receives the b₀(r) input from register 707 the other PEs of the ELU 230 receive their bⱼ₋₂(r) input each from two blocks right. Thus PE 730 receives its bⱼ₋₂(r) (=b₁(r)) input from block 710, and PE 740 receive its bⱼ₋₂(r) (=b₂(r)) input from bock 720 etc.

For the sake of brevity an example is set forth for depicting the functionality of block 710 as described in relations to FIG. 5. In this example the functionality of the hardware arrangement is described from the start of the process where r=0. At first, register 703 stores the value of V₀(o), which is equal to 1, as stated in the initial conditions of the process. Similarly, register 706 stores the value of b₁(0), which is equal to 0 and register 707 stores the value of b₀(o), which is equal to 1, as stated in the initial conditions of the process. When ELU 230 receives the inputs γ(0), δ(o) and MC(0), they are fed to block 710. At the first iteration the value of 706 (b₁(0)=0) is sent to block 730, as the b₁(0) input, and the value stored in register 703 (i.e. V₀(0)=1) is transmitted as output V₀(0) from ELU 230. The value stored in register 703 (i.e. V₀(0)=1) is also fed to MUX 705 together with the value of b₋₁(0) which is a null as stated in the initial conditions of the process. The MUX 705 is controlled by the conditional input MC(0) which decides if register 706 receives the V₀(0) value or the b₋₁(0) value. The new value of register 706 is now equal to the b₁(1) which will be used in the next iteration. From a different rout, the γ(0) input is multiplied, by FFM 701, with the value stored in register 703 (V₀(0)=1). Simultaneously, δ(0) input is multiplied, by FFM 704, by the value of b₋₁(0) which is a null as stated in the initial conditions of the process. The results from both multipliers 701 and 704 are added by FFA 702 and stored in register 703 and will be transmitted from ELU 230 as output V₀(1) in the next iteration. The inputs γ(0) and δ(0) are also passed to block 720. The registers of the other PEs start from the value of 0, as stated in the initial conditions of the process.

Continuing the example of the last paragraph, in the second iteration (r=1), the value of 706 is sent to block 730 as a b₁(1) input and the value stored in register 703 is transmitted as output V₀(1) from ELU 230. The same value stored in register 703 (i.e. V₀(1)) is also fed to MUX 705 together with the value of b₋₁(1) which is a null as stated in the initial conditions of the process. The MUX 705 is controlled by the control input MC(1) which decides if register 706 receives the V₀(1) value or the b₋₁(1) value. The new value of register 706 is now equal to the b₁(2) which will be used in the next iteration. From a different rout, the γ(1) input is multiplied, by FFM 701, with the value stored in register 703 (V₀(1)). Simultaneously, δ(1) input is multiplied, by multiplier 704, by the value of b₋₁(1) which is a null as stated in the initial conditions of the process. The results from both multipliers 701 and 704 are added by adder 702 and stored in register 703 for the next iteration as V₀(2). The inputs γ(1) and δ(1) are also passed to block 720.

While some embodiments of the invention have been described by way of illustration, it will be apparent that the invention can be carried into practice with many modifications, variations and adaptations, and with the use of numerous equivalents or alternative solutions that are within the scope of persons skilled in the art, without departing from the invention or exceeding the scope of claims.

1. A method for solving the key equation and finding the error locator polynomial coefficients of a received word comprising the steps of:
a. providing the syndrome elements of said received word;
b. initializing said coefficients of said error locator polynomial;
c. providing an auxiliary polynomial;
d. initializing said auxiliary polynomial coefficients;
e. processing said syndrome elements and said auxiliary polynomial coefficients for iteratively updating said coefficients of said error locator polynomial; and
f. outputting said updated coefficients of said error locator polynomial.

2. A method according to claim 1, where the processing of the syndrome elements and the auxiliary polynomial coefficients for iteratively updating said coefficients of said error locator polynomial, is done for t iterations.

3. A system for solving the key equation and finding the error locator polynomial coefficients of a received word comprising:
a. a Discrepancy Processor capable of processing the syndrome elements of said received word with coefficients of said error locator polynomial for outputting an auxiliary scalar;
b. a Control unit for receiving said auxiliary scalar, processing said auxiliary scalar, and outputting: said auxiliary scalar, a second scalar, and a conditional control bit; and
c. an Error Locator Updater for receiving and processing: said auxiliary scalar, said second scalar, and said conditional control bit, in order to update said coefficients of said error locator polynomial.
